(19) United States
(12) Patent Application Publication
(10) Pub. No.: US 2025/0239986 A1
(43) Pub. Date: Jul. 24, 2025

(54) MULTILAYER PIEZOELECTRIC SUBSTRATE SURFACE ACOUSTIC WAVE DEVICE WITH TEMPERATURE COMPENSATION STRUCTURE

(71) Applicant: Skyworks Solutions, Inc., Irvine, CA (US)

(72) Inventors: Michael David Hill, Emmitsburg, MD (US); Rei Goto, Osaka-Shi (JP)

(21) Appl. No.: 19/024,715

(22) Filed: Jan. 16, 2025

Related U.S. Application Data
(60) Provisional application No. 63/624,098, filed on Jan. 23, 2024.
(60) Provisional application No. 63/624,120, filed on Jan. 23, 2024.
(60) Provisional application No. 63/702,352, filed on Oct. 2, 2024.

(51) Int. Cl. H03H 9/02; H03H 9/145; H03H 9/64

(52) U.S. Cl. CPC H03H 9/02834; H03H 9/145; H03H 9/6483

(57) ABSTRACT

A surface acoustic wave device is disclosed. The surface acoustic wave device can include a support substrate, a piezoelectric layer over the support substrate, a temperature compensation structure between the support substrate and the piezoelectric layer, an interdigital transducer electrode in electrical communication with the piezoelectric layer. The temperature compensation structure includes a material having a lower acoustic velocity and higher permittivity than silicon oxide.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/624,098, filed Jan. 23, 2024, titled “SURFACE ACOUSTIC WAVE DEVICE WITH GERMANIUM OXIDE LAYER,” U.S. Provisional Patent Application No. 63/624,120, filed Jan. 23, 2024, titled “MULTILAYER PIEZOELECTRIC SUBSTRATE SURFACE ACOUSTIC WAVE DEVICE WITH TEMPERATURE COMPENSATION STRUCTURE,” and U.S. Provisional Patent Application No. 63/702,352, filed Oct. 2, 2024, titled “BULK ACOUSTIC WAVE DEVICE WITH TEMPERATURE COMPENSATION LAYER,” are hereby incorporated by reference under 37 CFR 1.57 in their entirety.

### BACKGROUND

### Technical Field

Embodiments of this disclosure relate to acoustic wave devices and in particular, to acoustic wave devices with a temperature compensation structure.

### Description of Related Technology

A surface acoustic wave filter can include a plurality of surface acoustic wave resonators arranged to filter a radio frequency signal. Each resonator can include a surface acoustic wave device. Example piezoelectric MEMS resonators include surface acoustic (SAW) resonators and temperature compensated surface acoustic wave (TC-SAW) resonators. A surface acoustic wave device can be configured to generate, for example, a Rayleigh mode surface acoustic wave in which the main mode of the acoustic wave generated by the surface acoustic wave device is Rayleigh mode, or a shear horizontal mode surface acoustic wave in which the main mode of the acoustic wave generated by the surface acoustic wave device is shear horizontal mode.

Surface acoustic wave filters can be implemented in radio frequency electronic systems. For instance, filters in a radio frequency front end of a mobile phone can include surface acoustic wave filters. A plurality of acoustic wave filters can be arranged as a multiplexer. For example, two surface acoustic wave filters can be arranged as a duplexer. Transverse leakage generally degrades the performance of the surface acoustic wave device.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a surface acoustic wave device including: a support substrate; a piezoelectric layer over the support substrate; a temperature compensation structure between the support substrate and the piezoelectric layer, the temperature compensation structure including a germanium oxide layer; and an interdigital transducer electrode in electrical communication with the piezoelectric layer.

In some embodiments, the techniques described herein relate to a surface acoustic wave device wherein the germanium oxide layer has a thickness in a range of 300 nm to 800 nm.

In some embodiments, the techniques described herein relate to a surface acoustic wave device wherein the piezoelectric layer has a thickness that is greater than a thickness of the germanium oxide layer.

In some embodiments, the techniques described herein relate to a surface acoustic wave device wherein the temperature compensation structure directly contacts the piezoelectric layer.

In some embodiments, the techniques described herein relate to a surface acoustic wave device wherein the temperature compensation structure has a multi-layer structure that includes the germanium oxide layer as a first layer and a second layer.

In some embodiments, the techniques described herein relate to a surface acoustic wave device wherein the second layer is a silicon oxide layer.

In some embodiments, the techniques described herein relate to a surface acoustic wave device wherein the temperature compensation structure has a thickness in a range of 300 nm to 1200 nm.

In some embodiments, the techniques described herein relate to a surface acoustic wave device wherein the germanium oxide layer has a thickness in a range of 0.1 L to 0.2 L where L is a wavelength generated by the surface acoustic wave device.

In some embodiments, the techniques described herein relate to a surface acoustic wave device wherein the piezoelectric layer has a thickness that is greater than a thickness of the temperature compensation structure.

In some embodiments, the techniques described herein relate to a surface acoustic wave device wherein the germanium oxide layer has a thickness in a range of 20% to 80% of a total thickness of the temperature compensation structure.

In some embodiments, the techniques described herein relate to a surface acoustic wave device further including a trap rich layer between the support substrate and the temperature compensation structure.

In some embodiments, the techniques described herein relate to a surface acoustic wave device wherein the piezoelectric layer includes lithium tantalate.

In some aspects, the techniques described herein relate to a surface acoustic wave device including: a piezoelectric layer; a temperature compensation structure in contact with the piezoelectric layer, the temperature compensation structure including a germanium oxide layer and a silicon oxide layer; and an interdigital transducer electrode in electrical communication with the piezoelectric layer.

In some embodiments, the techniques described herein relate to a surface acoustic wave device wherein the germanium oxide layer is provided between the piezoelectric layer and the silicon oxide layer.

In some embodiments, the techniques described herein relate to a surface acoustic wave device wherein the temperature compensation structure has a thickness in a range of 300 nm to 1200 nm.

In some embodiments, the techniques described herein relate to a surface acoustic wave device wherein the germanium oxide layer has a thickness in a range of 0.1 L to 0.2 L where L is a wavelength generated by the surface acoustic wave device.

In some embodiments, the techniques described herein relate to a surface acoustic wave device wherein the piezoelectric layer has a thickness that is greater than a thickness of the temperature compensation structure.

In some embodiments, the techniques described herein relate to a surface acoustic wave device wherein the germanium oxide layer has a thickness in a range of 20% to 80% of a total thickness of the temperature compensation structure.

In some embodiments, the techniques described herein relate to a surface acoustic wave device further including a support substrate and a trap rich layer, wherein the temperature compensation structure is positioned between the support substrate and the piezoelectric layer and the trap rich layer is positioned between the support substrate and the temperature compensation structure.

In some aspects, the techniques described herein relate to an acoustic wave filter including: a surface acoustic wave device including a support substrate, a piezoelectric layer over the support substrate, a temperature compensation structure between the support substrate and the piezoelectric layer, and an interdigital transducer electrode in electrical communication with the piezoelectric layer, the temperature compensation structure including a germanium oxide layer; and one or more acoustic wave resonators electrically coupled to the surface acoustic wave device.

In some aspects, the techniques described herein relate to a surface acoustic wave device including: a support substrate; a piezoelectric layer over the support substrate; a temperature compensation structure between the support substrate and the piezoelectric layer, the temperature compensation structure including a material having a lower acoustic velocity and higher permittivity than silicon oxide; and an interdigital transducer electrode in electrical communication with the piezoelectric layer.

In some embodiments, the techniques described herein relate to a surface acoustic wave device wherein the material of the temperature compensation structure has an acoustic velocity that is less than 70% of an acoustic velocity of silicon oxide.

In some embodiments, the techniques described herein relate to a surface acoustic wave device wherein the material of the temperature compensation structure has a permittivity that is more than 1.5 times a permittivity of the silicon oxide.

In some embodiments, the techniques described herein relate to a surface acoustic wave device wherein the temperature compensation structure has a thickness in a range of 300 nm to 800 nm.

In some embodiments, the techniques described herein relate to a surface acoustic wave device wherein the temperature compensation structure directly contacts the piezoelectric layer.

In some embodiments, the techniques described herein relate to a surface acoustic wave device wherein the temperature compensation structure has a multi-layer structure that includes a first layer having the material and a second layer.

In some embodiments, the techniques described herein relate to a surface acoustic wave device wherein the second layer is a silicon oxide layer.

In some embodiments, the techniques described herein relate to a surface acoustic wave device wherein the temperature compensation structure has a thickness in a range of 300 nm to 1200 nm.

In some embodiments, the techniques described herein relate to a surface acoustic wave device wherein the first layer has a thickness in a range of 0.1 L to 0.2 L where L is a wavelength generated by the surface acoustic wave device.

In some embodiments, the techniques described herein relate to a surface acoustic wave device wherein the piezoelectric layer has a thickness that is greater than a thickness of the temperature compensation structure.

In some embodiments, the techniques described herein relate to a surface acoustic wave device wherein the first layer has a thickness in a range of 20% to 80% of a total thickness of the temperature compensation structure.

In some embodiments, the techniques described herein relate to a surface acoustic wave device further including a trap rich layer between the support substrate and the temperature compensation structure.

In some embodiments, the techniques described herein relate to a surface acoustic wave device wherein the material of the temperature compensation structure includes germanium oxide, amorphous zinc phosphate, amorphous aluminum phosphate, amorphous gallium phosphate, amorphous silicon oxycarbide, or tellurium oxide.

In some embodiments, the techniques described herein relate to a surface acoustic wave device wherein the material of the temperature compensation structure has a lower acoustic velocity, a higher permittivity, and a higher effective electronegativity than silicon oxycarbide.

In some embodiments, the techniques described herein relate to a surface acoustic wave device wherein the material of the temperature compensation structure is a germanium-based material.

In some aspects, the techniques described herein relate to a surface acoustic wave device including: a piezoelectric layer; a temperature compensation structure in contact with the piezoelectric layer, the temperature compensation structure including a material having a lower acoustic velocity and higher permittivity than silicon oxide; and an interdigital transducer electrode in electrical communication with the piezoelectric layer.

In some embodiments, the techniques described herein relate to a surface acoustic wave device wherein the material of the temperature compensation structure has an acoustic velocity that is less than 70% of an acoustic velocity of silicon oxide.

In some embodiments, the techniques described herein relate to a surface acoustic wave device wherein the material of the temperature compensation structure has a permittivity that is more than 1.5 times a permittivity of the silicon oxide, and the temperature compensation structure has a thickness in a range of 300 nm to 800 nm.

In some embodiments, the techniques described herein relate to a surface acoustic wave device wherein the temperature compensation structure has a multi-layer structure that includes a first layer having the material and a second layer having silicon oxide.

In some embodiments, the techniques described herein relate to a surface acoustic wave device further including a support substrate, wherein the temperature compensation structure is positioned between the support substrate and the piezoelectric layer.

In some aspects, the techniques described herein relate to an acoustic wave filter including: a surface acoustic wave device including a support substrate, a piezoelectric layer over the support substrate, a temperature compensation structure between the support substrate and the piezoelectric layer, and an interdigital transducer electrode in electrical communication with the piezoelectric layer, the temperature compensation structure including a material having a lower acoustic velocity and higher permittivity than silicon oxide; and one or more acoustic wave resonators electrically coupled to the surface acoustic wave device.

In some aspects, the techniques described herein relate to a bulk acoustic wave device including: a first electrode; a second electrode; a piezoelectric layer positioned between the first electrode and the second electrode; and a temperature compensation structure in thermal communication with the piezoelectric layer, the temperature compensation structure including a material having a lower acoustic velocity and higher permittivity than silicon oxide.

In some embodiments, the techniques described herein relate to a bulk acoustic wave device wherein the material of the temperature compensation structure is a germanium-based material.

In some embodiments, the techniques described herein relate to a bulk acoustic wave device wherein the material of the temperature compensation structure includes a germanium oxide layer.

In some embodiments, the techniques described herein relate to a bulk acoustic wave device wherein the germanium oxide layer includes doped germanium oxide.

In some embodiments, the techniques described herein relate to a bulk acoustic wave device wherein the temperature compensation structure is positioned between the piezoelectric layer and the second electrode.

In some embodiments, the techniques described herein relate to a bulk acoustic wave device wherein the temperature compensation structure is embedded in the piezoelectric layer.

In some embodiments, the techniques described herein relate to a bulk acoustic wave device wherein the second electrode is positioned between the piezoelectric layer and the temperature compensation structure.

In some embodiments, the techniques described herein relate to a bulk acoustic wave device wherein the material of the temperature compensation structure has an acoustic velocity that is less than 70% of an acoustic velocity of silicon oxide.

In some embodiments, the techniques described herein relate to a bulk acoustic wave device wherein the material of the temperature compensation structure has a permittivity that is more than 1.5 times a permittivity of the silicon oxide.

In some embodiments, the techniques described herein relate to a bulk acoustic wave device wherein the temperature compensation structure has a thickness in a range of 300 nm to 800 nm.

In some embodiments, the techniques described herein relate to a bulk acoustic wave device wherein the temperature compensation structure directly contacts the piezoelectric layer.

In some embodiments, the techniques described herein relate to a bulk acoustic wave device wherein the temperature compensation structure has a multi-layer structure that includes a first layer having the material and a second layer.

In some embodiments, the techniques described herein relate to a bulk acoustic wave device wherein the second layer is a silicon oxide layer.

In some embodiments, the techniques described herein relate to a bulk acoustic wave device wherein the temperature compensation structure has a thickness in a range of 300 nm to 1200 nm.

In some embodiments, the techniques described herein relate to a bulk acoustic wave device wherein the first layer has a thickness in a range of 0.1 L to 0.2 L where L is a wavelength generated by the bulk acoustic wave device.

In some embodiments, the techniques described herein relate to a bulk acoustic wave device wherein the piezoelectric layer has a thickness that is greater than a thickness of the temperature compensation structure.

In some embodiments, the techniques described herein relate to a bulk acoustic wave device wherein the first layer has a thickness in a range of 20% to 80% of a total thickness of the temperature compensation structure.

In some embodiments, the techniques described herein relate to a bulk acoustic wave device wherein the material of the temperature compensation structure includes germanium oxide, amorphous zinc phosphate, amorphous aluminum phosphate, amorphous gallium phosphate, amorphous silicon oxycarbide, tellurium oxide, or beryllium fluoride.

In some embodiments, the techniques described herein relate to a bulk acoustic wave device wherein the material of the temperature compensation structure has a lower acoustic velocity, a higher permittivity, and a higher effective electronegativity than silicon oxycarbide.

In some aspects, the techniques described herein relate to a bulk acoustic wave device including: a first electrode; a second electrode; a piezoelectric layer positioned between the first electrode and the second electrode; and a temperature compensation structure in thermal communication with the piezoelectric layer, the temperature compensation structure including a germanium oxide layer.

In some embodiments, the techniques described herein relate to a bulk acoustic wave device wherein the temperature compensation structure is positioned between the first electrode and the second electrode.

In some aspects, the techniques described herein relate to an acoustic wave filter including: a bulk acoustic wave device including a first electrode, a second electrode, a piezoelectric layer positioned between the first electrode and the second electrode, and a temperature compensation structure in thermal communication with the piezoelectric layer, the temperature compensation structure including a material having a lower acoustic velocity and higher permittivity than silicon oxide; and one or more acoustic wave resonators electrically coupled to the bulk acoustic wave device.

In some aspects, the techniques described herein relate to a bulk acoustic wave device including: a first electrode; a second electrode; a piezoelectric layer positioned between the first electrode and the second electrode; and a temperature compensation structure, the second electrode is positioned between the piezoelectric layer and the temperature compensation structure, the temperature compensation structure including a material having a lower acoustic velocity and higher permittivity than silicon oxide, a thickness of the temperature compensation structure and a thickness of the piezoelectric layer excite a higher order mode as a main mode.

In some embodiments, the techniques described herein relate to a bulk acoustic wave device wherein the material of the temperature compensation structure has a lower acoustic velocity, a higher permittivity, and a higher effective electronegativity than silicon oxycarbide.

In some embodiments, the techniques described herein relate to a bulk acoustic wave device wherein the material of the temperature compensation structure is a germanium-based material.

In some embodiments, the techniques described herein relate to a bulk acoustic wave device wherein the temperature compensation structure incldues a germanium oxide layer.

In some embodiments, the techniques described herein relate to a bulk acoustic wave device wherein the germanium oxide layer includes doped germanium oxide.

In some embodiments, the techniques described herein relate to a bulk acoustic wave device wherein the material of the temperature compensation structure has an acoustic velocity that is less than 70% of an acoustic velocity of silicon oxide.

In some embodiments, the techniques described herein relate to a bulk acoustic wave device wherein the material of the temperature compensation structure has a permittivity that is more than 1.5 times a permittivity of the silicon oxide.

In some embodiments, the techniques described herein relate to a bulk acoustic wave device wherein the temperature compensation structure has a thickness in a range of 300 nm to 800 nm.

In some embodiments, the techniques described herein relate to a bulk acoustic wave device wherein the temperature compensation structure directly contacts the piezoelectric layer.

In some embodiments, the techniques described herein relate to a bulk acoustic wave device wherein the temperature compensation structure has a multi-layer structure that includes a first layer having the material and a second layer.

In some embodiments, the techniques described herein relate to a bulk acoustic wave device wherein the second layer is a silicon oxide layer.

In some embodiments, the techniques described herein relate to a bulk acoustic wave device wherein the temperature compensation structure has a thickness in a range of 300 nm to 1200 nm.

In some embodiments, the techniques described herein relate to a bulk acoustic wave device wherein the first layer has a thickness in a range of 0.1 L to 0.2 L where L is a wavelength generated by the bulk acoustic wave device.

In some embodiments, the techniques described herein relate to a bulk acoustic wave device wherein the piezoelectric layer has a thickness that is greater than a thickness of the temperature compensation structure.

In some embodiments, the techniques described herein relate to a bulk acoustic wave device wherein the first layer has a thickness in a range of 20% to 80% of a total thickness of the temperature compensation structure.

In some embodiments, the techniques described herein relate to a bulk acoustic wave device wherein the material of the temperature compensation structure includes germanium oxide, amorphous zinc phosphate, amorphous aluminum phosphate, amorphous gallium phosphate, amorphous silicon oxycarbide, tellurium oxide, or beryllium fluoride.

In some aspects, the techniques described herein relate to a bulk acoustic wave device including: a first electrode; a second electrode; a piezoelectric layer positioned between the first electrode and the second electrode; and a temperature compensation structure in thermal communication with the piezoelectric layer, the temperature compensation structure including a germanium oxide layer.

In some embodiments, the techniques described herein relate to a bulk acoustic wave device wherein the temperature compensation structure is positioned between the first electrode and the second electrode.

In some aspects, the techniques described herein relate to an acoustic wave filter including: a bulk acoustic wave device including a first electrode, a second electrode, a piezoelectric layer positioned between the first electrode and the second electrode, and a temperature compensation structure, the second electrode is positioned between the piezoelectric layer and the temperature compensation structure, the temperature compensation structure including a material having a lower acoustic velocity and higher permittivity than silicon oxide, a thickness of the temperature compensation structure and a thickness of the piezoelectric layer excite a higher order mode as a main mode; and one or more acoustic wave resonators electrically coupled to the bulk acoustic wave device.

In some embodiments, the techniques described herein relate to an acoustic wave filter wherein the material of the temperature compensation structure has a lower acoustic velocity, a higher permittivity, and a higher effective electronegativity than silicon oxycarbide.

The present disclosure relates to U.S. patent application Ser. No.______[Attorney Docket SKYWRKS. 1509A1], titled “SURFACE ACOUSTIC WAVE DEVICE WITH GERMANIUM OXIDE LAYER,” U.S. patent application Ser. No.______[Attorney Docket SKYWRKS.1509A3], titled “BULK ACOUSTIC WAVE DEVICE WITH TEMPERATURE COMPENSATION LAYER,” and U.S. patent application Ser. No.______[Attorney Docket SKYWRKS.1509A4], titled “HIGHER ORDER MODE BULK ACOUSTIC WAVE DEVICE WITH TEMPERATURE COMPENSATION LAYER,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1 is a schematic cross-sectional side view of a multilayer piezoelectric substrate (MPS) surface acoustic wave (SAW) device.

FIG. 2 is a schematic cross-sectional side view of an MPS-SAW device according to an embodiment.

FIG. 3 is a graph showing simulated frequency response results of the SAW device of FIGS. 1 and 2.

FIGS. 4A to 7E are simulation results that compare various performance factors of the SAW devices.

FIG. 8A is a graph showing relationships between the size and the coupling coefficient of the SAW devices of FIGS. 1 and 2.

FIG. 8B is a graph showing relationships between the TCF and the coupling coefficient of the SAW devices of FIGS. 1 and 2.

FIG. 9 is a schematic cross-sectional side view of a an MPS-SAW device according to an embodiment.

FIGS. 10A, 10B, 10C, and 10D are graphs showing simulation results of various performance factors of the SAW devices of FIG. 9 with different thicknesses of first and second temperature compensation layers.

FIGS. 11A-11C are simulation results showing coupling coefficient, acoustic velocity, and static capacitance of the SAW devices of FIG. 9 for different thicknesses of first and second temperature compensation layers.

FIG. 12A is a schematic cross-sectional side view of a temperature compensated surface acoustic wave (TC-SAW) device according to an embodiment.

FIGS. 12B-12F are schematic cross-sectional side views of bulk acoustic wave (BAW) devices according to embodiments.

FIG. 13A is a schematic diagram of a ladder filter that includes an acoustic wave resonator according to an embodiment.

FIG. 13B is a schematic diagram of a transmit filter that includes a surface acoustic wave resonator according to an embodiment.

FIG. 13C is a schematic diagram of a receive filter that includes a surface acoustic wave resonator according to an embodiment.

FIG. 14 is a schematic diagram of a radio frequency module that includes a surface acoustic wave component according to an embodiment.

FIG. 15 is a schematic diagram of a radio frequency module that includes filters with surface acoustic wave resonators according to an embodiment.

FIG. 16A is a schematic block diagram of a wireless communication device that includes a filter in accordance with one or more embodiments.

FIG. 16B is a schematic block diagram of another wireless communication device that includes a filter in accordance with one or more embodiments.

FIG. 17 is a schematic block diagram of a wireless communication device that includes a filter according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. The surface acoustic wave devices include, for example, SAW resonators, SAW delay lines, and multi-mode SAW (MMS) filters (e.g., double mode SAW (DMS) filters).

In general, high quality factor (Q), large effective electromechanical coupling coefficient or coupling factor (K²), high frequency ability, and spurious free can be significant aspects for micro resonators to enable low-loss filters, stable oscillators, and sensitive sensors. In some SAW devices, performance can be degraded when a magnitude of a temperature coefficient of frequency (TCF) is large. Therefore, a temperature compensation layer can be provided to bring the TCF of the SAW device closer to zero. A thickness of the temperature compensation layer can affect the TCF, the coupling coefficient K², and spurious of the resonator under which the temperature compensation layer is disposed.

A temperature compensation layer can be provided over an interdigital transducer (IDT) electrode in a SAW device to define a temperature compensated (TC) SAW device. In the TC-SAW device, the IDT electrode is positioned between the piezoelectric layer and the temperature compensation layer. Another structure that can be beneficial for compensating the temperature increase in the SAW device is a multi-layer piezoelectric substrate (MPS) structure. An MPS-SAW device can include a support substrate, a piezoelectric layer over the support substrate, and the IDT electrode over the piezoelectric layer. There may be one or more functional layers provided between the support substrate and the piezoelectric layer. MPS-SAW devices can thermally insulate an interdigital transducer electrode and a piezoelectric layer. By reducing dissipative thermal impedance of the SAW device, the ruggedness and power handling can be improved. Silicon dioxide (SiO₂) is known to have a positive TCF which can bring the TCF of the SAW device closer to zero. Therefore, SiO₂ has been used in SAW devices (e.g., the TC-SAW device or the MPS SAW device) as a temperature compensation layer. The SiO₂ layer can be provided between the support substrate and the piezoelectric layer for improving the temperature coefficient of frequency of the MPS SAW device.

The TC-SAW device includes a relatively thick, high permittivity substrate, such as a lithium niobate (LN) layer having a cut angle in a range between about 118° (118° Y-cut X-propagation LN) and about 132° (132Y-cut X-propagation LN) or less. A multi-layer piezoelectric substrate (MPS) SAW device can have a relatively thin film type of piezoelectric layer such as a lithium tantalate LT layer having a cut angle in a range between about 20° (42° Y-cut X-propagation LT) and about 60° (60° Y-cut X-propagation LT). A thinner piezoelectric layer can reduce the static capacitance between interdigital transducer electrodes. Therefore, the MPS SAW devices may have a greater footprint than the TC SAW devices. Also, the propagation mode used in the MPS-SAW devices may be higher than the TC-SAW devices, which can also contribute to increasing the size of the MPS-SAW devices as compared to the TC-SAW devices. The greater size of the MPS-SAW devices as compared to the TC-SAW devices can increase a size of the module that implements the MPS-SAW devices and/or increase the cost per wafer for manufacturing the MPS-SAW devices.

In various embodiments disclosed herein, surface acoustic wave (SAW) devices (e.g., MPS-SAW devices) include a temperature compensation structure including a material having a lower acoustic velocity and higher permittivity than silicon oxide (e.g., silicon dioxide (SiO₂)). A SAW device according to some embodiments, can include a support substrate, the temperature compensation structure over the support substrate, a piezoelectric layer over the temperature compensation layer, and an interdigital transducer electrode in electrical communication with the piezoelectric layer. In some embodiments, the material of the temperature compensation structure can be germanium oxide (e.g., germanium dioxide (GeO₂)). The temperature compensation structure disclosed herein can provide lower acoustic velocity thereby enabling a size reduction as compared to a SiO₂ temperature compensation layer. The temperature compensation structure disclosed herein can have a multilayer structure that includes two or more temperature compensation layers. For example, the temperature compensation structure can include a GeO₂ layer and a SiO₂ layer.

FIG. 1 is a schematic cross-sectional side view of a multilayer piezoelectric substrate (MPS) surface acoustic wave (SAW) device 1. The SAW device 1 includes a silicon substrate 10, a polycrystalline silicon layer 12 over the silicon substrate 10, a silicon dioxide (SiO₂) layer 14 over the polycrystalline silicon layer 12, a lithium tantalate (LT) layer 16 over the SiO₂ layer 14, and an interdigital transducer (IDT) electrode 18 on the LT layer 16. The IDT electrode 18 includes a molybdenum (Mo) layer 18a and an aluminum (Al) layer 18b. As described above, the MPS SAW devices, such as the SAW device 1, may have a greater footprint than the TC SAW devices.

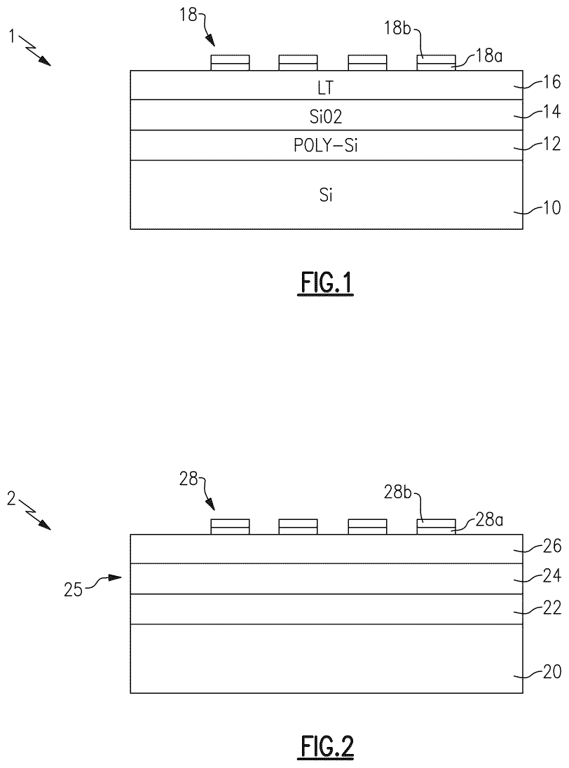

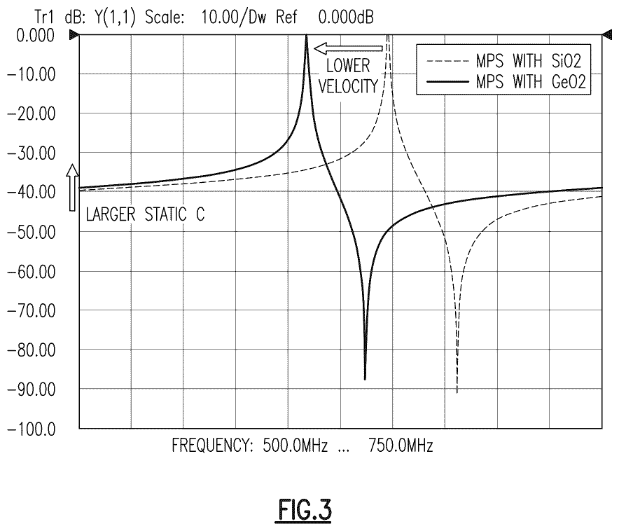

FIG. 2 is a schematic cross-sectional side view of a multilayer piezoelectric substrate (MPS) surface acoustic wave (SAW) device 2 according to an embodiment. The SAW device 2 can include a support substrate 20, trap rich layer 22 over the support substrate 20, a temperature compensation layer 24 over the trap rich layer 22, a piezoelectric layer 26 over the temperature compensation layer 24, and an interdigital transducer (IDT) electrode 28 in electrical communication with (e.g., formed over, on, in, with, within, or at least partially in) the piezoelectric layer 26. The temperature compensation layer 24 can define a temperature compensation structure 25. The IDT electrode 28 can include a first layer 28a and a second layer 28b.

The support substrate 20 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, or the like. The support substrate 20 can have a relatively high acoustic impedance. An acoustic impedance of the support substrate 20 can be higher than an acoustic impedance of the piezoelectric layer 26. For instance, the support substrate 20 can have a higher acoustic impedance than an acoustic impedance of lithium niobate and a higher acoustic impedance than lithium tantalate. The acoustic impedance of the support substrate 20 can be higher than an acoustic impedance of silicon dioxide (SiO₂). The SAW device 2 including the piezoelectric layer 26 on a support substrate 20 with relatively high thermal conductivity, such as silicon substrate, can achieve better thermal dissipation compared to a similar SAW device without the high impedance support substrate 20.

The trap rich layer 22 can be formed at, near, on, or with the support substrate 20. In some embodiments, the trap rich layer 22 can mitigate the parasitic surface conductivity of the support substrate 20. The trap rich layer 22 can be formed in a number of ways, for example, by forming the surface of the support substrate 20 with amorphous or polycrystalline silicon, by forming the surface of the support substrate 20 with porous silicon, or by introducing defects into the surface of the support substrate 20 via ion implantation, ion milling, or other methods. In some embodiments, the trap rich layer 22 can improve the electrical characteristics of the SAW device 2 by increasing the depth and sharpness on the anti-resonance peak.

The temperature compensation structure 25 (e.g., the temperature compensation layer 24) can be in contact with the piezoelectric layer 26. The temperature compensation layer 24 can include a material having a lower acoustic velocity (e.g., less than 70% or less than 60%) and higher permittivity (e.g., more than 1.5 times or 2 times) than silicon oxide (e.g., silicon dioxide (SiO₂)). In some embodiments, the material of the temperature compensation layer 24 has a lower acoustic velocity, a higher permittivity, and a higher effective electronegativity than silicon oxycarbide. Materials which crystallize with the cristobalite structure tend to have positive temperature coefficients of the elastic modulus in the vitreous state. These materials can include amorphous zinc phosphate, amorphous aluminum phosphate, amorphous gallium phosphate, and amorphous silicon oxycarbide. Tellurium oxide can also have a high dielectric constant and a positive temperature coefficient of the elastic modulus. The acoustic velocity of SiO₂ can be about 3800 m/s and the permittivity of SiO₂ can be about 3.5. to 4.6. In some embodiments, the material of the temperature compensation layer 24 can be a germanium-based material. For example, the material of the temperature compensation layer 24 can be germanium oxide (e.g., germanium dioxide (GeO₂)) which has the acoustic velocity of about 2100 m/s and the permittivity of about 9. For example, the temperature compensation layer 24 can be doped germanium oxide. In some other embodiments, the temperature compensation layer 24 can include zinc phosphate (e.g., amorphous zinc phosphate (Zn₃(PO₄)₂), aluminum phosphate (e.g., amorphous aluminum phosphate (AlPO₄), gallium phosphate (e.g., amorphous gallium phosphate (GaPO₄), silicon oxycarbide (e.g., amorphous silicon oxycarbide), tellurium oxide (TeO₂), or beryllium fluoride (BeF₂). In some embodiments, there can be two or more temperature compensation layers defining the temperature compensation structure 25 (see FIG. 9).

Some materials that have a lower thermal conductivity as compared to silicon dioxide (SiO₂), such as germanium dioxide (GeO₂), can cost more than silicon dioxide (SiO₂). Therefore, implementation of Materials other than silicon dioxide (SiO₂), such as germanium dioxide (GeO₂), can be less advantageous in certain applications, and silicon dioxide (SiO₂) has been used as a temperature compensation layer in MPS SAW devices as shown in FIG. 1. However, the temperature compensation layer 24 disclosed herein can provide lower acoustic velocity, as shown in FIG. 3, thereby enabling a size reduction as compared to a SiO₂ temperature compensation layer. For example, implementation of germanium dioxide (GeO₂) in accordance with various principles and advantages disclosed herein can provide various benefits (e.g., size reduction, an improved static capacitance, a more positive TCF, etc.) over silicon dioxide (SiO₂). Such benefits may outweigh the disadvantages in some applications.

The piezoelectric layer 26 can include lithium tantalate (LT). For example, the piezoelectric layer 26 can be an LT layer having a cut angle of 20° (20° Y-cut X-propagation LT) or a cut angle of 60° (60° Y-cut X-propagation LT). For example, the piezoelectric layer 26 can be 20±10° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 26. For example, the piezoelectric layer 26 can be an LN layer having a cut angle of about 118° (118° Y-cut X-propagation LN) or more or a cut angle of about 132° (132Y-cut X-propagation LN) or less. For example, the piezoelectric layer 26 can be 125±20° Y-cut LN, 125±15° Y-cut LN, 125±10° Y-cut LN, or 125±5° Y-cut LN. In some embodiments, use of the LN layer in the piezoelectric layer 26 can provide an improved coupling coefficient.

A thickness of the piezoelectric layer 26 can be selected based on a wavelength/or L of a surface acoustic wave generated by the SAW device 2 in certain applications. The IDT electrode 28 can have a pitch that set the wavelengths λ or L. The pitches of the IDT electrode 28 can be modulated in some applications. The piezoelectric layer 26 can be sufficiently thick to avoid significant frequency variation.

The IDT electrode 28 can include any suitable material. The IDT electrode 28 may include one or more metals, such as aluminum (Al), copper (Cu), Magnesium (Mg), titanium (Ti), tungsten (W), molybdenum (Mo), etc. The IDT electrode 28 may include alloys, such as AlMgCu, AlCu, etc. In some embodiments, the IDT electrode 28 can have a multi-layer IDT electrode that includes more than two layers. For example, the IDT electrode 28 can include first and second layers 28a, 28b. The first layer 28a can include molybdenum (Mo) and the second layer 28b can include aluminum (Al) in certain embodiments.

FIG. 3 is a graph showing simulated frequency response results of the SAW device 1 of FIG. 1 (labeled MPS with SiO₂) and an example of the SAW device 2 of FIG. 2 (labeled MPS with GeO₂). In the simulation, a silicon substrate is used as the support substrate 20, a polycrystalline silicon layer is used as the trap rich layer 22, a GeO₂ layer is used as the temperature compensation layer 24, a lithium tantalate (LT) layer is used as the piezoelectric layer 26, a molybdenum layer is used as the first layer 28a, and an aluminum layer is used as the second layer 28b. Therefore, the SAW device 2 used in the simulation of FIG. 3 is different from the SAW device 1 in that the GeO₂ layer is used in place of the SiO₂ layer 14.

FIG. 3 indicates that the GeO₂ layer can significantly decrease the acoustic velocity in the SAW device 2 as compared to the SAW device 1. FIG. 3 also indicates that the GeO₂ layer can significantly increase the static capacitance in the SAW device 2 as compared to the SAW device 1. Accordingly, the GeO₂ layer can enable size reduction of the SAW device 2 as compared to the SAW device 1 while improving the performance of the device in certain aspects.

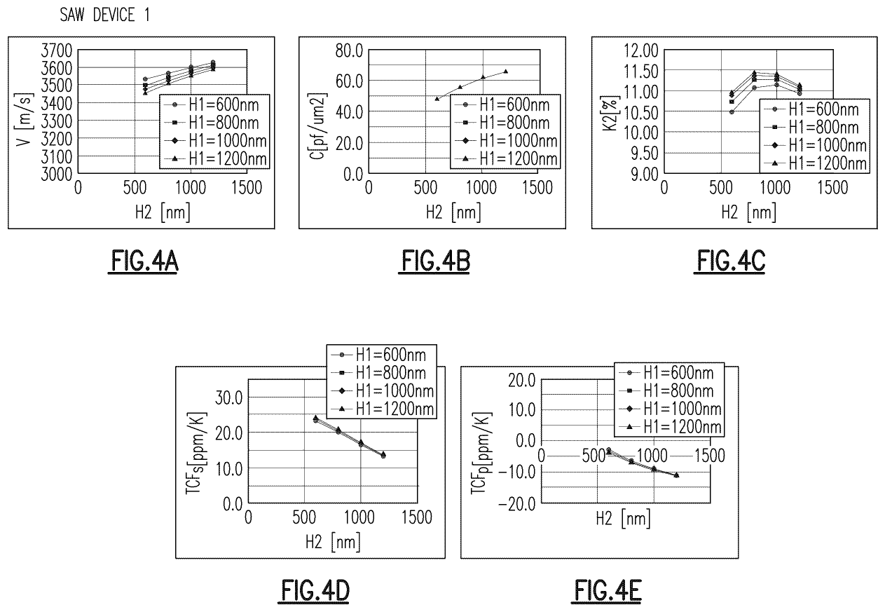

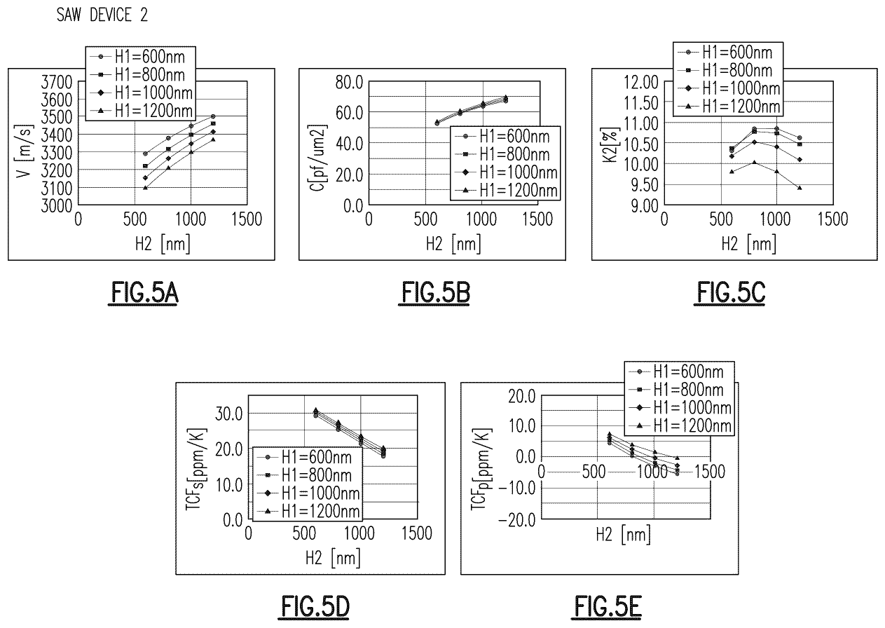

FIGS. 4A-4E and 5A-5E are simulation results that compare various performance factors of the SAW devices 1, 2. The materials of the layers in the SAW device 2 used in the simulations of FIGS. 5A-5E are the same as the materials of the layers in the SAW device 2 used in the simulation of FIG. 3. In the simulations of FIGS. 4A-4E and 5A-5E various thicknesses of the SiO₂ layer 14, the LT layer 16, the temperature compensation layer 24 (the GeO₂ layer), and the piezoelectric layer 26 (the LT layer) were used. The x-axes indicate the thicknesses of the SiO₂ layer 14 and the GeO₂ layer.

FIGS. 4A-4E and 5A-5E indicate that implementing the GeO₂ layer as the temperature compensation layer 24 can lower the acoustic velocity, increase the static capacitance, and provide a more positive TCF as compared to the SiO₂ layer 14. Also, the coupling coefficient can be maintained at a relatively high value for certain GeO₂ thicknesses. FIGS. 5A-5E indicate that as the thickness of the GeO₂ layer increases, the acoustic velocity increases, the static capacitance increases, and the TCF becomes less positive. The coupling coefficient increases to a certain thickness (e.g., about 750 nm) of the GeO₂ layer and decreases as the thickness increases above the certain thickness. Also, FIGS. 4A-4E and 5A-5E indicate that as the thickness of the piezoelectric layer 26 increases, the acoustic velocity decreases, the coupling coefficient decreases, and the TCF becomes more positive.

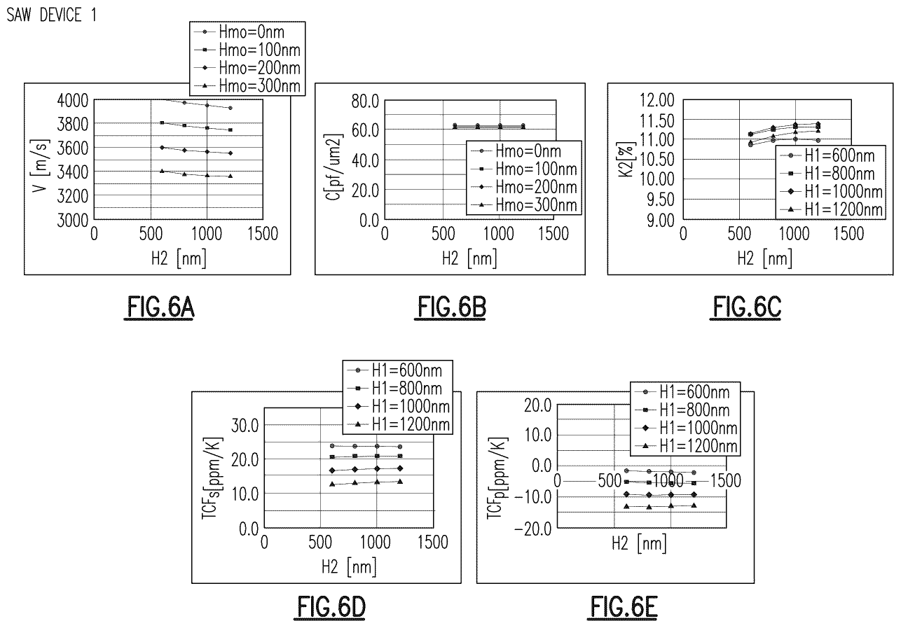

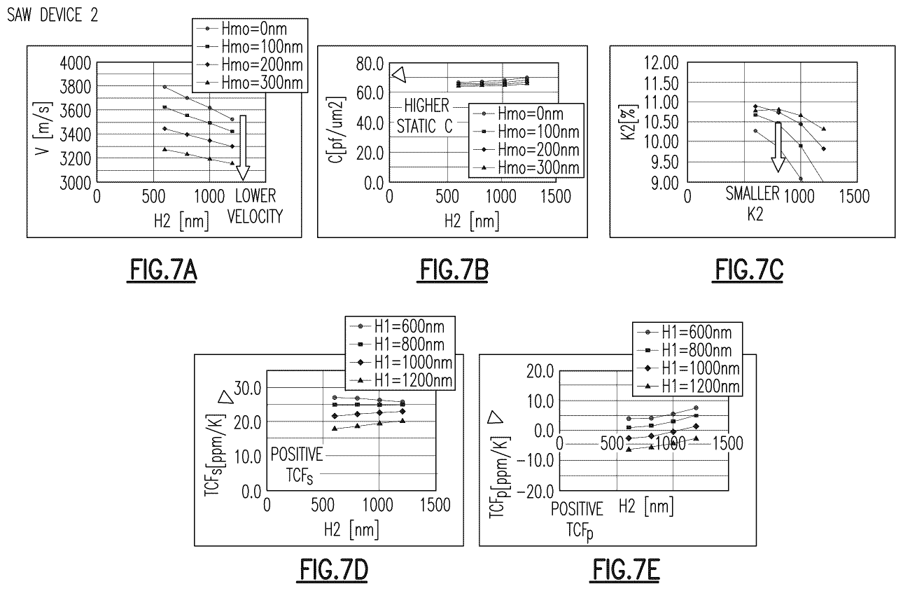

FIGS. 6A-6E and 7A-7E are simulation results that compare various performance factors of the SAW devices 1, 2. The materials of the layers in the SAW device 2 used in the simulations of FIGS. 7A-7E are the same as the materials of the layers in the SAW device 2 used in the simulation of FIG. 3. In the simulations of FIGS. 6A-6E and 7A-7E various thicknesses of the SiO₂ layer 14, the Mo layer 18a, the temperature compensation layer 24 (the GeO₂ layer), and the first layer 28 (the Mo layer) were used. The x-axes indicate the thicknesses of the SiO₂ layer 14 and the GeO₂ layer. FIGS. 7A-7E indicate that as the thickness of the first layer 28 (the Mo layer) increases, the acoustic velocity decreases, the coupling coefficient increases, and the TCF becomes less positive.

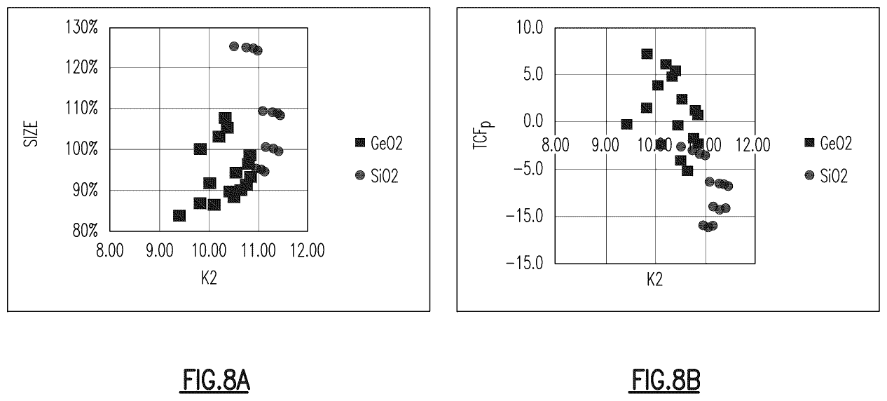

FIG. 8A is a graph showing relationships between the size and the coupling coefficient of the SAW devices 1, 2. FIG. 8B is a graph showing relationships between the TCF and the coupling coefficient of the SAW devices 1, 2. The materials of the layers in the SAW device 2 used in the simulations of FIGS. 8A and 8B are the same as the materials of the layers in the SAW device 2 used in the simulation of FIG. 3.

FIGS. 8A and 8B indicate that for certain thicknesses of the GeO₂ as the temperature compensation layer 24 can provide a comparatively high coupling coefficient as the SiO₂ as the temperature compensation layer while making the size of the SAW device 2 smaller than the SAW device 1. FIGS. 8A and 8B also indicate that for certain thicknesses of the GeO₂ as the temperature compensation layer 24 can provide a more positive TCF while maintaining a relatively high coupling coefficient.

As the device performance can significantly alter based at least in part on dimensions or sizes and/or the materials of the layers in the SAW device 2, it can be significant to carefully select the materials and thicknesses of the layers in the SAW device to provide an optimal or desired performance. In some embodiments, a thickness of the temperature compensation layer 24 can be in a range of, for example, 300 nm to 800 nm, 500 nm to 800 nm, 300 nm to 600 nm, or 500 nm to 600 nm. In some embodiments, the thickness of the temperature compensation layer 24 can be in a range of 0.1 L to 0.2 L, 0.15 L to 0.2 L, or 0.1 L to 0.15 L where L is the wavelength generated by the SAW device 2. In some embodiments, the thickness of the temperature compensation layer 24 can be a thickness of the piezoelectric layer 26 or smaller. In order to further improve the performance of the SAW device 2, the temperature compensation structure 25 can include a plurality of layers.

FIG. 9 is a schematic cross-sectional side view of a multilayer piezoelectric substrate (MPS) surface acoustic wave (SAW) device 3 according to an embodiment. Unless otherwise noted, the components of the SAW device 3 shown in FIG. 9 may be structurally and/or functionally the same as or generally similar to like components of the SAW device 2 of FIG. 2. Unlike the temperature compensation structure 25 of the SAW device 2, the temperature compensation structure 25 of the SAW device 3 include a first temperature compensation layer 24a and a second temperature compensation layer 24b.

The temperature compensation structure 25 can include any suitable temperature compensation material layers. For example, one of the first and second temperature compensation layers 24a, 24b can be a silicon dioxide (SiO₂) layer and the other one of the first and second temperature compensation layers 24a, 24b can be a germanium dioxide (GeO₂) layer. One of the first and second temperature compensation layers 24a, 24b can be a layer of any other suitable material having a positive temperature coefficient of frequency for SAW resonators with a piezoelectric layer 26 having a negative coefficient of frequency, and the other one of the first and second temperature compensation layers 24a, 24b can have a material that is a lower acoustic velocity and higher permittivity than the one of the first and second temperature compensation layers 24a, 24b. For instance, the one of the first and second temperature compensation layers 24a, 24b can be a tellurium dioxide (TeO₂) layer or a silicon oxyfluoride (SiOF) layer in certain applications. The one of the first and second temperature compensation layers 24a, 24b can include any suitable combination of SiO₂, TeO₂, and/or SiOF.

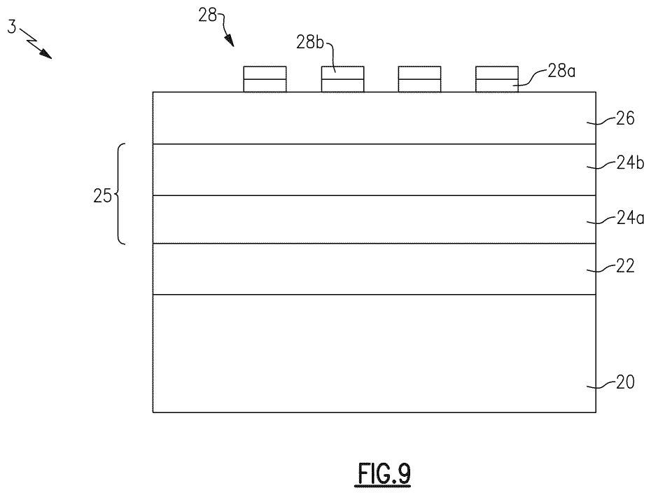

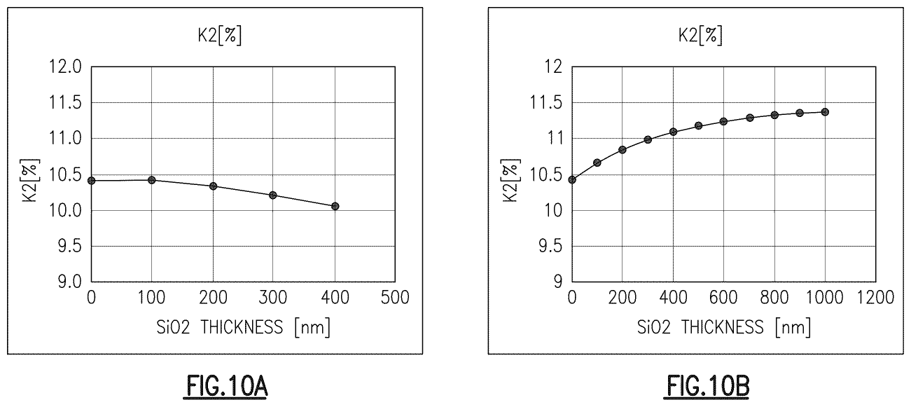

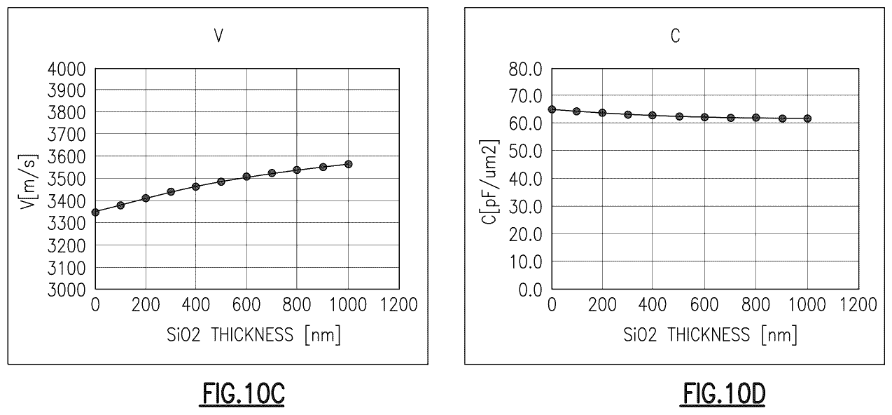

Various material combinations and/or thickness combinations of the first and second temperature compensation layers 24a, 24b can enable further optimization of the performance of the SAW device 3. FIGS. 10A, 10B, 10C, and 10D are graphs showing simulation results of various performance factors of the SAW devices 3 with different thicknesses of the first and second temperature compensation layers 24a, 24b. In the simulations of FIGS. 10A-10D, a germanium dioxide (GeO₂) layer is used as the first temperature compensation layer 24a and a silicon dioxide (SiO₂) layer is used as the second temperature compensation layer 24b.

In some embodiments, a thickness of the temperature compensation structure 25 can be in a range of, for example, 300 nm to 1200 nm, 300 nm to 1000 nm, 500 nm to 1200 nm, 300 nm to 800 nm, 500 nm to 800 nm, 300 nm to 600 nm, or 500 nm to 600 nm. In some embodiments, a thickness of the first temperature compensation structure 24a can be in a range of, for example, 300 nm to 800 nm, 500 nm to 800 nm, 300 nm to 600 nm, or 500 nm to 600 nm. In some embodiments, the thickness of the temperature compensation layer 24 can be in a range of 0.1 L to 0.2 L, 0.15 L to 0.2 L, or 0.1 L to 0.15 L where L is the wavelength generated by the SAW device 2. In some embodiments, the thickness of the temperature compensation layer 24 can be a thickness of the piezoelectric layer 26 or smaller. In some embodiments, when one of the first and second temperature compensation layers 24a, 24b includes a GeO₂ layer, the GeO₂ layer can have a thickness that is in a rage of 20% to 80% or 30% to 60% of the thickness of the temperature compensation structure 25.

FIGS. 10A are 10B are simulation results showing coupling coefficient of the SAW devices 3 for different thicknesses of the first and second temperature compensation layers 24a, 24b. In the simulation of FIG. 10A, the thickness of the first temperature compensation layer 24a (the GeO₂ layer) is fixed to 1000 nm, the thickness of the piezoelectric layer 26 is fixed to 1000 nm. FIG. 10A shows the coupling coefficient values of the SAW device 3 for thicknesses of the second temperature compensation layer 24b (the SiO₂ layer) at 0 nm, 100 nm, 200 nm, 300 nm, and 400 nm. In the simulation of FIG. 10B, the total thickness of the temperature compensation structure 25 is fixed to 1000 nm. FIG. 10B shows the coupling coefficient values of the SAW device 3 for thicknesses of the second temperature compensation layer 24b (the SiO₂ layer) at 0 nm, 100 nm, 200 nm, 300 nm, 400 nm, 500 nm, 600 nm, 700 nm, 800 nm, 900 nm, and 1000 nm. FIGS. 10C are 10D are simulation results showing the acoustic velocity and the static capacitance of the SAW devices 3 for different thicknesses of the first and second temperature compensation layers 24a, 24b. In the simulations of FIGS. 10C are 10D, the total thickness of the temperature compensation structure 25 is fixed to 1000 nm.

FIG. 10A indicates that as the thickness of the SiO₂ layer increases, the coupling coefficient decreases, and FIG. 10B indicates that as the proportion of the SiO₂ layer increases, the coupling coefficient increases. FIG. 10C indicates that the as the proportion of the SiO₂ layer increases, the acoustic velocity increases, and FIG. 10D indicates that as the proportion of the SiO₂ layer increases, the static capacitance decreases. Therefore, a careful selection of the thicknesses of the first and second temperature compensation layers 24a, 24b can be significant in providing a SAW device with optimal performance.

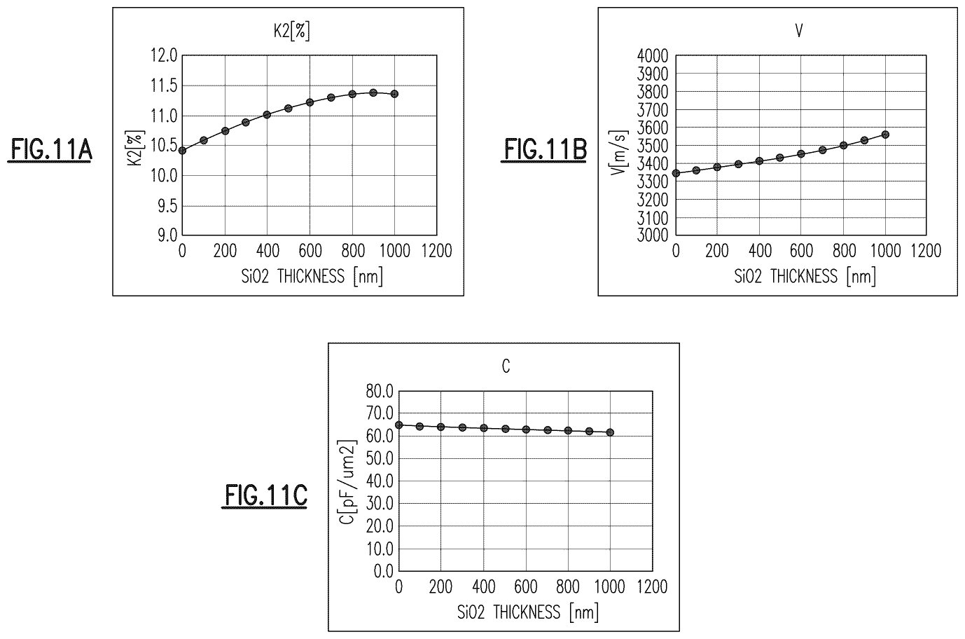

FIGS. 11A-11C are simulation results showing coupling coefficient, acoustic velocity, and static capacitance of the SAW devices 3 for different thicknesses of the first and second temperature compensation layers 24a, 24b. In the simulations of FIGS. 11A-11C, a silicon dioxide (SiO₂) layer is used as the first temperature compensation layer 24a and a germanium dioxide (GeO₂) layer is used as the second temperature compensation layer 24b. In the simulations of FIGS. 11A-11C, the total thickness of the temperature compensation structure 25 is fixed to 1000 nm.

FIG. 11A indicates that as the proportion of the SiO₂ layer increases, the coupling coefficient increases, FIG. 11B indicates that the as the proportion of the SiO₂ layer increases, the acoustic velocity increases, and FIG. 11C indicates that as the proportion of the SiO₂ layer increases, the static capacitance decreases. Also, FIGS. 11A-11C indicates that switching the first and second temperature compensation layers 24a, 24b does not significantly alter the performance of the SAW device 3.

FIGS. 2 and 9 illustrate the use of the temperature compensation structure 25 in connection with multilayer piezoelectric substrate (MPS) surface acoustic wave (SAW) devices 2, 3. However, the principles and advantages disclosed herein may be implemented in other types of acoustic wave devices, such as a temperature compensated surface acoustic wave (TC-SAW) device or a bulk acoustic wave (BAW) device.

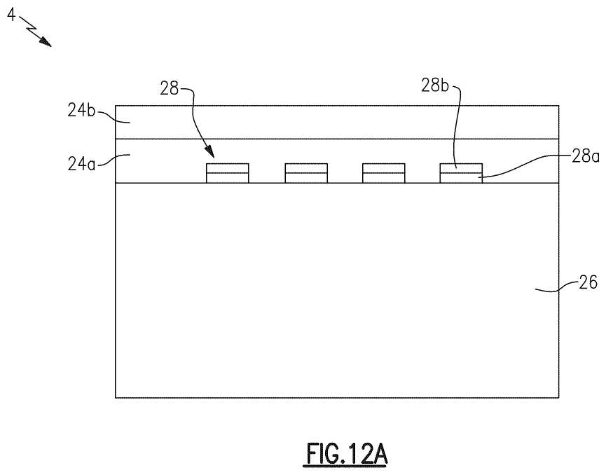

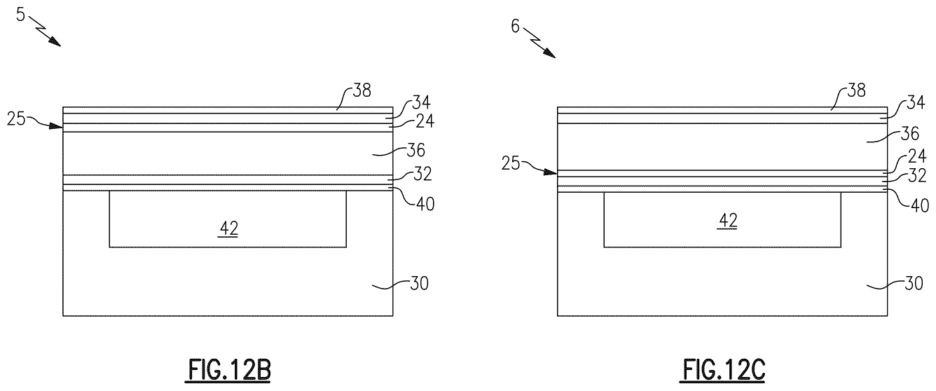

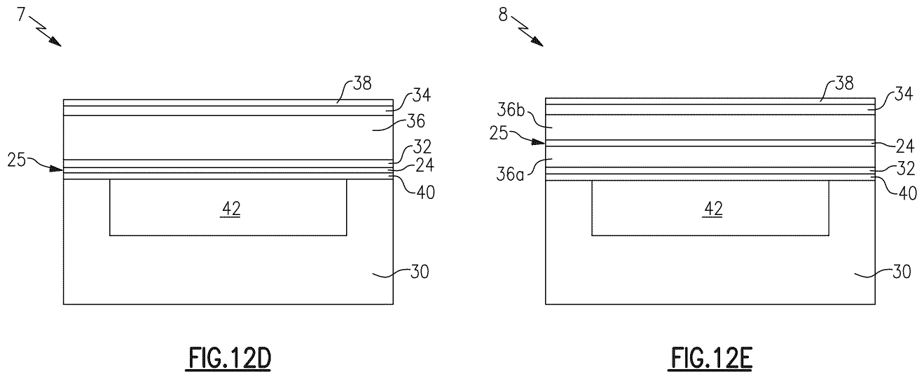

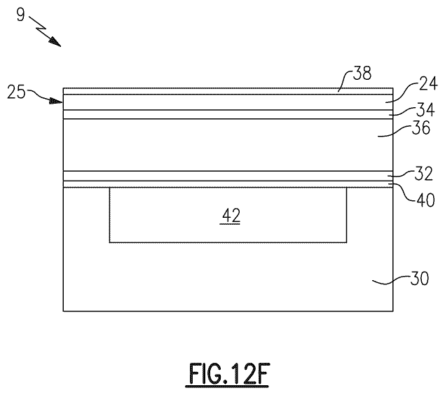

FIG. 12A is a schematic cross-sectional side view of a temperature compensated (TC) surface acoustic wave (SAW) device 4 according to an embodiment. Unless otherwise noted, the components of the SAW device 4 shown in FIG. 12A may be structurally and/or functionally the same as or generally similar to like components of the SAW devices 2, 3 of FIGS. 2 and 9. The functions of the temperature compensation layers 24a, 24b in the TC-SAW device 4 can be different in some aspect from those of the MPS SAW devices. Implementation of a temperature compensation layer that includes a material having a lower acoustic velocity and higher permittivity than silicon oxide (e.g., silicon dioxide (SiO₂)) can be more beneficial in the MPS SAW devices than in the TC-SAW devices as the temperature compensation layer can affect the capacitance and the side of the MPS SAW devices.

FIGS. 12B to 12F are schematic cross-sectional side views of BAW devices 5, 6, 7, 8, 9 according to various embodiments. Unless otherwise noted, the components of the SAW devices 5, 6, 7, 8, 9 shown in FIGS. 12B to 12F may be structurally and/or functionally the same as or generally similar to like components of other figures disclosed herein.

The BAW deice 5 can include a support substrate 30, a first electrode 32, a second electrode 34, a piezoelectric layer between the first and second electrodes 32, 34, a temperature compensation structure 25 between the first and third electrodes 32, 34, a passivation layer 38, and an intermediate layer 40 between the first electrode 32 and the support substrate 30.

The temperature compensation structure 25 (e.g., the temperature compensation layer 24) can be in contact with the piezoelectric layer 36 and positioned between the piezoelectric layer 36 and the second electrode 34 as shown in FIG. 12B. However, the temperature compensation structure 25 may be positioned in any other suitable locations as shown in, for example, FIGS. 12C to 12F.

The temperature compensation layer 24 can include a material having a lower acoustic velocity (e.g., less than 70% or less than 60%) and higher permittivity (e.g., more than 1.5 times or 2 times) than silicon oxide (e.g., silicon dioxide (SiO₂)). Materials which crystallize with the cristobalite structure tend to have positive temperature coefficients of the elastic modulus in the vitreous state. These materials can include amorphous zinc phosphate, amorphous aluminum phosphate, amorphous gallium phosphate, and amorphous silicon oxycarbide. Tellurium oxide can also have a high dielectric constant and a positive temperature coefficient of the elastic modulus. The acoustic velocity of SiO₂ can be about 3800 m/s and the permittivity of SiO₂ can be about 3.5. to 4.6. In some embodiments, the material of the temperature compensation layer 24 can be germanium oxide (e.g., germanium dioxide (GeO₂)) which has the acoustic velocity of about 2100 m/s and the permittivity of about 9. For example, the temperature compensation layer 24 can be doped germanium oxide. In some other embodiments, the temperature compensation layer 24 can include zinc phosphate (e.g., amorphous zinc phosphate (Zn₃(PO₄)₂), aluminum phosphate (e.g., amorphous aluminum phosphate (AlPO₄), gallium phosphate (e.g., amorphous gallium phosphate (GaPO₄), silicon oxycarbide (e.g., amorphous silicon oxycarbide), tellurium oxide (TeO₂), or beryllium fluoride (BeF₂). In some embodiments, there can be two or more temperature compensation layers defining the temperature compensation structure 25 (not shown).

The temperature compensation structure 25 including the temperature compensation layer 24 can maintain a relatively high coupling coefficient k2 while improving the temperature coefficient of frequency of the BAW device 5 as compared to when a silicon oxide is implemented in place of the temperature compensation structure 25. Also, the temperature compensation structure 25 can reduce the acoustic velocity and provide a higher permittivity, thereby enabling size reduction of the BAW device 5.

The support substrate 30 can be a semiconductor substrate. The support substrate 30 can be a silicon substrate. The support substrate 30 can be any other suitable support substrate, such as a substrate of quartz, silicon carbide, sapphire, glass, gallium arsenide, or any suitable ceramic (e.g., spinel, alumina, etc.). The support substrate 30 can be part of a support structure that includes, for example, the support substrate 30, a trap rich layer (not shown), a passivation layer (not shown), or one or more intermediate layers therebetween (not shown).

An air cavity 42 can be formed between the substrate 30 and the first electrode 32. The cavity 42 is an example of an acoustic reflector. The BAW device 5 can be a film bulk acoustic wave resonator (FBAR). In some other embodiments, there can be a solid acoustic mirror in place of the cavity 42 and such a BAW device can be a BAW solidly mounted resonator (SMR).

The first electrode 32 can be referred to as a lower electrode. The first electrode 32 can have a relatively high acoustic impedance. The first electrode 32 can include molybdenum (Mo), tungsten (W), ruthenium (Ru), chromium (Cr), iridium (Ir), platinum (Pt), or any suitable alloy and/or combination thereof. Similarly, the second electrode 34 can have a relatively high acoustic impedance. The second electrode 34 can include Mo, W, Ru, Cr, Ir, Pt, or any suitable alloy and/or combination thereof. The second electrode 34 can be formed of the same material as the first electrode 32 in certain applications. The second electrode 34 can be referred to as an upper electrode.

The piezoelectric layer 36 can include a suitable material such as, but not limited to, aluminum nitride (AlN), zinc oxide (ZnO), or lead zirconium titanate (PZT). In certain applications, the piezoelectric layer 36 can be an AlN layer. The piezoelectric material can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain applications, the piezoelectric layer 36 can be AlN based layer doped with Sc. Doping the piezoelectric layer 36 can adjust the resonant frequency. Doping the piezoelectric layer 36 can increase the electromechanical coupling coefficient (kt²) of the BAW device 5. Doping to increase the kt² can be advantageous at higher frequencies where kt² can be degraded.

The passivation layer 38 is positioned over the second electrode 34. The passivation layer 38 can be a silicon dioxide layer or any other suitable passivation layer, such as a layer including aluminum oxide, silicon carbide, aluminum nitride, silicon nitride, silicon oxynitride, or the like. The passivation layer 38 can have different thicknesses in different regions of the BAW device 5. In some embodiments, the passivation layer 38 can also function as a frequency trimming layer.

The intermediate layer 40 can include, for example, one or more of a seed layer, a trap rich layer, a passivation layer, or one or more other suitable functional layers. In some embodiments, the intermediate layer 40 can be completely or partially omitted. In some such embodiments, a portion of the first electrode 40 can directly contact the support substrate 30. The intermediate layer 40 can be relatively thin. For example, the intermediate layer 40 can be significantly thinner than the support substrate 30.

As shown in FIG. 12C, the temperature compensation structure 25 can be positioned between the first electrode 32 and the piezoelectric layer 36, in some embodiments. As shown in FIG. 12D, the temperature compensation structure 25 can be positioned between the intermediate layer 40 and the first electrode 32, in some other embodiments. As shown in FIG. 12E, the temperature compensation structure 25 can be embedded in the piezoelectric layer 36, in some other embodiments. As shown in FIG. 12F, the temperature compensation structure 25 can be positioned over the second electrode 34, in some other embodiments.

When the temperature compensation structure 25 is positioned outside of an area between the first and second electrodes 32, 34 (see FIGS. 12D and 12F), the temperature compensation structure 25 can be sufficiently thick to excite an overtone mode as a main mode. For example, a thickness of the temperature compensation structure 25 can be configured to generate a second order mode, a third order mode, or any other higher order mode as the main mode of the BAW device 7, 9. In the BAW devices 7, 9, the temperature compensation structure 25 can create an asymmetry on opposing sides of the piezoelectric layer 36 sufficient to excite an overtone mode as a main mode. The main mode can be a mode associated with a highest coupling Kt² among modes generated by a BAW device. The main mode can be an operating mode of the BAW device. The thickness of the temperature compensation structure 25 that can generate an overtone mode as the main mode can be in a range of 250 nm to 1200 nm, 300 nm to 1200 nm, 250 nm to 800 nm, 300 nm to 800 nm, or 250 nm to 500 nm. In some embodiments, two or more temperature compensation structures 25 can be included in different locations of a single BAW device.

In some embodiments, a piston mode structure can be implemented with a surface acoustic wave device that implements any suitable principles and advantages disclosed herein. The piston mode structure can contribute to transverse mode suppression enabling further performance improvement of a SAW device. In some embodiments, a frame structure can be implemented with a bulk acoustic wave device that implements any suitable principles and advantages disclosed herein. The frame structure can include a raised frame structure and/or a recessed frame structure. There may be a frame mode suppression structure that can suppress the frame mode associated with the frame structure.

The acoustic wave devices (e.g., the SAW devices and/or BAW devices) disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

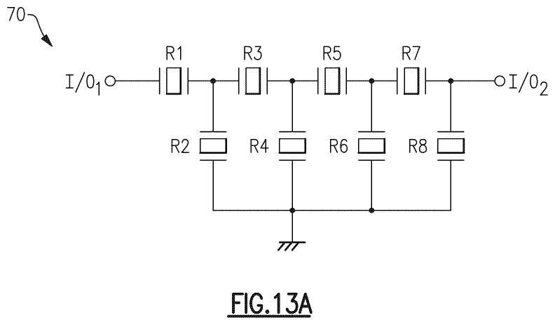

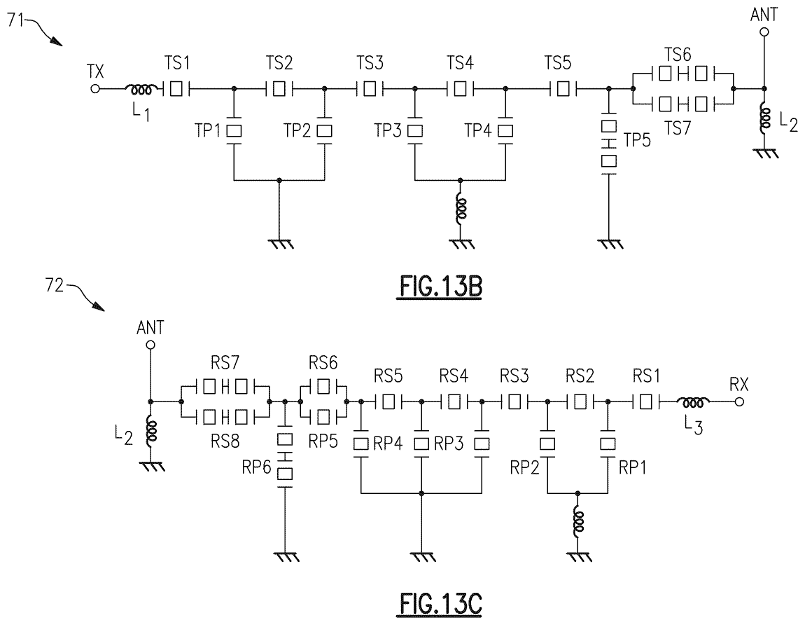

FIG. 13A is a schematic diagram of a ladder filter 70 that includes an acoustic wave resonator according to an embodiment. The ladder filter 70 is an example topology that can implement a band pass filter formed from acoustic wave resonators. In a band pass filter with a ladder filter topology, the shunt resonators can have lower resonant frequencies than the series resonators. The ladder filter 70 can be arranged to filter a radio frequency signal. As illustrated, the ladder filter 70 includes series acoustic wave resonators R1, R3, R5, and R7 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can a transmit port and the second input/output port I/O₂ can be an antenna port. Alternatively, first input/output port I/O₁ can be a receive port and the second input/output port I/O₂ can be an antenna port.

FIG. 13B is a schematic diagram of an example transmit filter 71 that includes surface acoustic wave resonators of a surface acoustic wave component according to an embodiment. The transmit filter 71 can be a band pass filter. The illustrated transmit filter 71 is arranged to filter a radio frequency signal received at a transmit port TX and provide a filtered output signal to an antenna port ANT. The transmit filter 71 includes series SAW resonators TS1, TS2, TS3, TS4, TS5, TS6, and TS7, shunt SAW resonators TP1, TP2, TP3, TP4, and TP5, series input inductor L1, and shunt inductor L2. Some or all of the SAW resonators TS1, TS2, TS3, TS4, TS5, TS6, and TS7 and/or TP1, TP2, TP3, TP4, and TP5 can be a SAW resonators with a conductive strip for transverse mode suppression. For instance, one or more of the SAW resonators of the transmit filter 71 can be any surface acoustic wave resonator disclosed herein. Any suitable number of series SAW resonators and shunt SAW resonators can be included in a transmit filter 71.

FIG. 13C is a schematic diagram of a receive filter 72 that includes surface acoustic wave resonators of a surface acoustic wave component according to an embodiment. The receive filter 72 can be a band pass filter. The illustrated receive filter 72 is arranged to filter a radio frequency signal received at an antenna port ANT and provide a filtered output signal to a receive port RX. The receive filter 72 includes series SAW resonators RS1, RS2, RS3, RS4, RS5, RS6, RS7, and RS7, shunt SAW resonators RP1, RP2, RP3, RP4, and RP5, and RP6, shunt inductor L2, and series output inductor L3. Some or all of the SAW resonators RS1, RS2, RS3, RS4, RS5, RS6, RS7, and RS8 and/or RP1, RP2, RP3, RP4, RP5, and RP6 can be SAW resonators with a conductive strip for transverse mode suppression. For instance, one or more of the SAW resonators of the receive filter 72 can be any surface acoustic wave resonator disclosed herein. Any suitable number of series SAW resonators and shunt SAW resonators can be included in a receive filter 72.

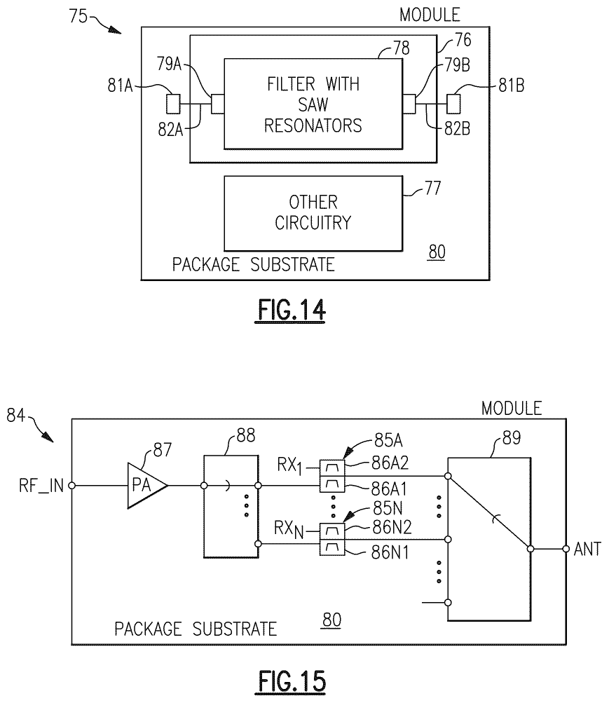

FIG. 14 is a schematic diagram of a radio frequency module 75 that includes a surface acoustic wave component 76 according to an embodiment. The illustrated radio frequency module 75 includes the SAW component 76 and other circuitry 77. The SAW component 76 can include one or more SAW resonators with any suitable combination of features of the SAW resonators and/or acoustic wave devices disclosed herein. The SAW component 76 can include a SAW die that includes SAW resonators.

The SAW component 76 shown in FIG. 14 includes a filter 78 and terminals 79A and 79B. The filter 78 includes SAW resonators. One or more of the SAW devices can be implemented in accordance with any suitable principles and advantages of any surface acoustic wave devices disclosed herein. The filter 78 can be a TC-SAW filter arranged as a band pass filter to filter radio frequency signals with frequencies below about 3.5 GHz in certain applications. The terminals 79A and 78B can serve, for example, as an input contact and an output contact. The SAW component 76 and the other circuitry 77 are on a common packaging substrate 80 in FIG. 14. The packaging substrate 80 can be a laminate substrate. The terminals 79A and 79B can be electrically connected to contacts 81A and 81B, respectively, on the packaging substrate 80 by way of electrical connectors 82A and 82B, respectively. The electrical connectors 82A and 82B can be bumps or wire bonds, for example. The other circuitry 77 can include any suitable additional circuitry. For example, the other circuitry can include one or more power amplifiers, one or more radio frequency switches, one or more additional filters, one or more low noise amplifiers, the like, or any suitable combination thereof. The radio frequency module 75 can include one or more packaging structures to, for example, provide protection and/or facilitate easier handling of the radio frequency module 75. Such a packaging structure can include an overmold structure formed over the packaging substrate 80. The overmold structure can encapsulate some or all of the components of the radio frequency module 75.

FIG. 15 is a schematic diagram of a radio frequency module 84 that includes a surface acoustic wave component according to an embodiment. As illustrated, the radio frequency module 84 includes duplexers 85A to 85N that include respective transmit filters 86A1 to 86N1 and respective receive filters 86A2 to 86N2, a power amplifier 87, a select switch 88, and an antenna switch 89. The radio frequency module 84 can include a package that encloses the illustrated elements. The illustrated elements can be disposed on a common packaging substrate 80. The packaging substrate can be a laminate substrate, for example.

The duplexers 85A to 85N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 86A1 to 86N1 can include one or more SAW resonators in accordance with any suitable principles and advantages disclosed herein. Similarly, one or more of the receive filters 86A2 to 86N2 can include one or more SAW resonators in accordance with any suitable principles and advantages disclosed herein. Although FIG. 15 illustrates duplexers, any suitable principles and advantages disclosed herein can be implemented in other multiplexers (e.g., quadplexers, hexaplexers, octoplexers, etc.) and/or in switch-plexers.

The power amplifier 87 can amplify a radio frequency signal. The illustrated switch 88 is a multi-throw radio frequency switch. The switch 88 can electrically couple an output of the power amplifier 87 to a selected transmit filter of the transmit filters 86A1 to 86N1. In some instances, the switch 88 can electrically connect the output of the power amplifier 87 to more than one of the transmit filters 86A1 to 86N1. The antenna switch 89 can selectively couple a signal from one or more of the duplexers 85A to 85N to an antenna port ANT. The duplexers 85A to 85N can be associated with different frequency bands and/or different modes of operation (e.g., different power modes, different signaling modes, etc.).

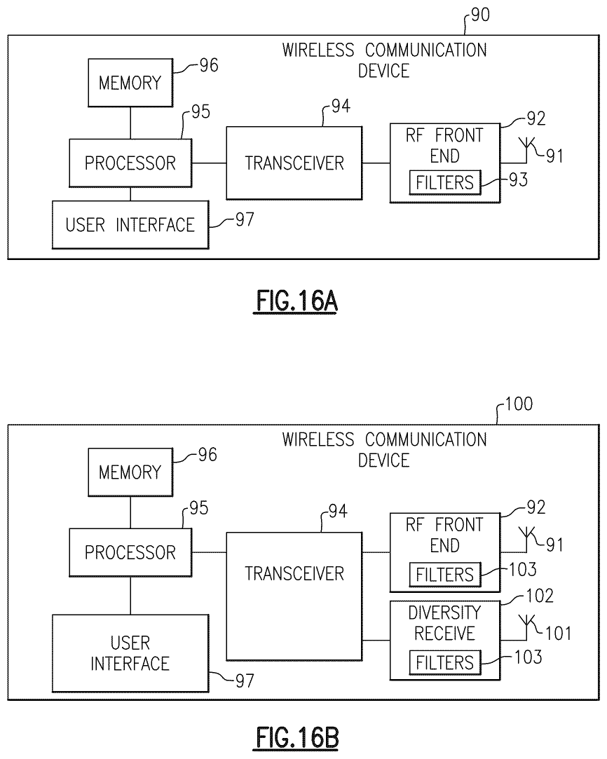

FIG. 16A is a schematic diagram of a wireless communication device 90 that includes filters 93 in a radio frequency front end 92 according to an embodiment. The filters 93 can include one or more SAW resonators in accordance with any suitable principles and advantages discussed herein. The wireless communication device 90 can be any suitable wireless communication device. For instance, a wireless communication device 90 can be a mobile phone, such as a smart phone. As illustrated, the wireless communication device 90 includes an antenna 91, an RF front end 92, a transceiver 94, a processor 95, a memory 96, and a user interface 97. The antenna 91 can transmit RF signals provided by the RF front end 92. Such RF signals can include carrier aggregation signals. Although not illustrated, the wireless communication device 90 can include a microphone and a speaker in certain applications.

The RF front end 92 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 92 can transmit and receive RF signals associated with any suitable communication standards. The filters 93 can include SAW resonators of a SAW component that includes any suitable combination of features discussed with reference to any embodiments discussed above.

The transceiver 94 can provide RF signals to the RF front end 92 for amplification and/or other processing. The transceiver 94 can also process an RF signal provided by a low noise amplifier of the RF front end 92. The transceiver 94 is in communication with the processor 95. The processor 95 can be a baseband processor. The processor 95 can provide any suitable base band processing functions for the wireless communication device 90. The memory 96 can be accessed by the processor 95. The memory 96 can store any suitable data for the wireless communication device 90. The user interface 97 can be any suitable user interface, such as a display with touch screen capabilities.

FIG. 16B is a schematic diagram of a wireless communication device 100 that includes filters 93 in a radio frequency front end 92 and a second filter 103 in a diversity receive module 102. The wireless communication device 100 is like the wireless communication device 90 of FIG. 16A, except that the wireless communication device 100 also includes diversity receive features. As illustrated in FIG. 16B, the wireless communication device 100 includes a diversity antenna 101, a diversity module 102 configured to process signals received by the diversity antenna 101 and including filters 103, and a transceiver 104 in communication with both the radio frequency front end 92 and the diversity receive module 102. The filters 103 can include one or more SAW resonators that include any suitable combination of features discussed with reference to any embodiments discussed above.

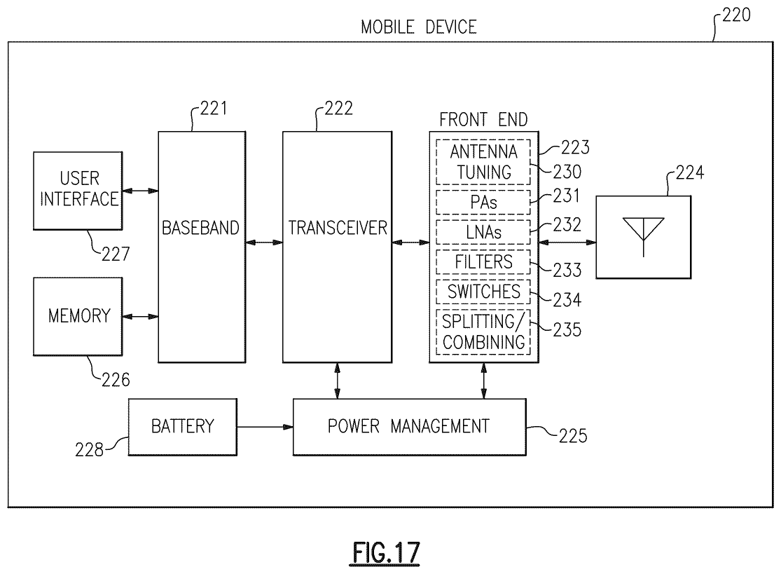

FIG. 17 is a schematic block diagram of a wireless communication device 220 that includes a filter according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 17 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAs) 231, low noise amplifiers (LNAs) 232, filters 233, switches 234, and signal splitting/combining circuitry 235. However, other implementations are possible. The filters 233 can include one or more acoustic wave filters that include any suitable number of acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 17, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 17, the power management system 225 receives a battery voltage from the battery 228. The battery 228 can be any suitable battery for use in the wireless communication device 220, including, for example, a lithium-ion battery.

Any suitable principles and advantages of the surface acoustic wave devices disclosed herein can be implemented with one or more temperature compensated SAW resonators. Temperature compensated SAW resonators include a temperature compensation layer (e.g., a silicon dioxide layer) over an interdigital transducer electrode to bring a temperature coefficient of frequency closer to zero.

Packaged surface acoustic wave devices disclosed herein can include one or more surface acoustic wave resonators included in a filter arranged to filter a radio frequency signal in a fourth generation (4G) Long Term Evolution (LTE) operating band. Packaged surface acoustic wave devices disclosed herein can include one or more surface acoustic wave resonators included in a filter arranged to filter a radio frequency signal in a fifth generation (5G) New Radio (NR) operating band within Frequency Range 1 (FR1). FR1 can be from 410 megahertz (MHz) to 7.125 gigahertz (GHz), for example, as specified in a current 5G NR specification. Packaged surface acoustic wave devices disclosed herein can include one or more surface acoustic wave resonators included in a filter with a passband corresponding to both a 4G LTE operating band and a 5G NR operating band within FR1.

Any of the embodiments disclosed herein can combined. Any of the embodiments described above can be implemented in association with a radio frequency system and/or mobile devices such as cellular handsets. The principles and advantages of the embodiments can be used for any systems or apparatus that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals in a frequency range from about 30 KHz to 300 GHz, such as in a frequency range from about 450 MHz to 8.5 GHz, a frequency range from about 450 MHz to 2.5 GHZ, or a frequency range from about 450 MHz to 3 GHz.

Aspects of this disclosure can be implemented in various electronic devices. Examples of the electronic devices can include, but are not limited to, consumer electronic products, parts of the consumer electronic products such as semiconductor die and/or packaged radio frequency modules, electronic test equipment, uplink wireless communication devices, personal area network communication devices, etc. Examples of the consumer electronic products can include, but are not limited to, a mobile phone such as a smart phone, a wearable computing device such as a smart watch or an ear piece, a telephone, a television, a computer monitor, a computer, a router, a modem, a hand-held computer, a laptop computer, a tablet computer, a personal digital assistant (PDA), a microwave, a refrigerator, a vehicular electronics system such as an automotive electronics system, a stereo system, a DVD player, a CD player, a digital music player such as an MP3 player, a radio, a camcorder, a camera such as a digital camera, a portable memory chip, a washer, a dryer, a washer/dryer, a peripheral device, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a support substrate;
a piezoelectric layer over the support substrate;
a temperature compensation structure between the support substrate and the piezoelectric layer, the temperature compensation structure including a material having a lower acoustic velocity and higher permittivity than silicon oxide; and
an interdigital transducer electrode in electrical communication with the piezoelectric layer.

2. The surface acoustic wave device of claim 1 wherein the material of the temperature compensation structure has an acoustic velocity that is less than 70% of an acoustic velocity of silicon oxide.

3. The surface acoustic wave device of claim 1 wherein the material of the temperature compensation structure has a permittivity that is more than 1.5 times a permittivity of the silicon oxide.

4. The surface acoustic wave device of claim 1 wherein the temperature compensation structure has a thickness in a range of 300 nm to 800 nm.

5. The surface acoustic wave device of claim 1 wherein the temperature compensation structure directly contacts the piezoelectric layer.

6. The surface acoustic wave device of claim 1 wherein the temperature compensation structure has a multi-layer structure that includes a first layer having the material and a second layer.

7. The surface acoustic wave device of claim 6 wherein the temperature compensation structure has a thickness in a range of 300 nm to 1200 nm.

8. The surface acoustic wave device of claim 6 wherein the first layer has a thickness in a range of 0.1 L to 0.2 L where L is a wavelength generated by the surface acoustic wave device.

9. The surface acoustic wave device of claim 6 wherein the piezoelectric layer has a thickness that is greater than a thickness of the temperature compensation structure.

10. The surface acoustic wave device of claim 6 wherein the first layer has a thickness in a range of 20% to 80% of a total thickness of the temperature compensation structure.

11. The surface acoustic wave device of claim 1 further comprising a trap rich layer between the support substrate and the temperature compensation structure.

12. The surface acoustic wave device of claim 1 wherein the material of the temperature compensation structure includes germanium oxide, amorphous zinc phosphate, amorphous aluminum phosphate, amorphous gallium phosphate, amorphous silicon oxycarbide, or tellurium oxide.

13. The surface acoustic wave device of claim 1 wherein the material of the temperature compensation structure has a lower acoustic velocity, a higher permittivity, and a higher effective electronegativity than silicon oxycarbide.

14. The surface acoustic wave device of claim 1 wherein the material of the temperature compensation structure is a germanium-based material.

15. A surface acoustic wave device comprising:
a piezoelectric layer;
a temperature compensation structure in contact with the piezoelectric layer, the temperature compensation structure including a material having a lower acoustic velocity and higher permittivity than silicon oxide; and
an interdigital transducer electrode in electrical communication with the piezoelectric layer.

16. The surface acoustic wave device of claim 15 wherein the material of the temperature compensation structure has an acoustic velocity that is less than 70% of an acoustic velocity of silicon oxide.

17. The surface acoustic wave device of claim 15 wherein the material of the temperature compensation structure has a permittivity that is more than 1.5 times a permittivity of the silicon oxide, and the temperature compensation structure has a thickness in a range of 300 nm to 800 nm.

18. The surface acoustic wave device of claim 15 wherein the temperature compensation structure has a multi-layer structure that includes a first layer having the material and a second layer having silicon oxide.

19. The surface acoustic wave device of claim 15 further comprising a support substrate, wherein the temperature compensation structure is positioned between the support substrate and the piezoelectric layer.

20. An acoustic wave filter comprising:
a surface acoustic wave device including a support substrate, a piezoelectric layer over the support substrate, a temperature compensation structure between the support substrate and the piezoelectric layer, and an interdigital transducer electrode in electrical communication with the piezoelectric layer, the temperature compensation structure including a material having a lower acoustic velocity and higher permittivity than silicon oxide; and
one or more acoustic wave resonators electrically coupled to the surface acoustic wave device.
